(19) United States
(12) Patent Application Publication
(10) Pub. No.: US 2021/0389360 A1
(43) Pub. Date: Dec. 16, 2021

(54) SYSTEMS FOR DETECTING ELECTRICAL FAULTS IN A VEHICLE

(71) Applicant: Transportation IP Holdings, LLC, Norwalk, CT (US)

(72) Inventors: Jared Klineman Cooper, Palm Bay, FL (US); David Michael Peltz, Melbourne, FL (US); Nicholas David Nagrodsky, Melbourne, FL (US); Samuel William Golden, Melbourne, FL (US); Jerod Reid Svidunovich, Melbourne, FL (US); Keith Allen Heob, Melbourne, FL (US); Michael Copps, Melbourne, FL (US)

(21) Appl. No.: 17/446,363

(22) Filed: Aug. 30, 2021

Related U.S. Application Data
(63) Continuation-in-part of application No. 16/726,994, filed on Dec. 26, 2019, now Pat. No. 11,125,799.
Application No. 16/726,994 is a continuation of application No. 16/373,262, filed on Apr. 2, 2019, now Pat. No. 10,557,885.
Application No. 16/373,262 is a continuation of application No. 14/993,078, filed on Jan. 11, 2016, now Pat. No. 10,288,666.
(60) Provisional application No. 62/101,399, filed on Jan. 9, 2015.

(51) Int. Cl. G01R 31/08

(52) U.S. Cl. CPC G01R 31/086; G01R 31/007

(57) ABSTRACT

A system includes a location unit to direct one or more distributions of electrical signals through different conductive pathways of conductive pathways to plural components of an electric system. The location unit receives a modified version of one or more of the electric signals that is modified by passage through one or more of the conductive pathways. The location unit determines a location of an electric fault based on a position where the modified version is measured in its passage through one or more conductive pathways. A coupling unit couples the location unit to the electrical system. A method includes distributing plural electrical signals through different conductive pathways to several components of an electric system, receiving a modified version of one or more electric signals, and determining a location of an electric fault in the electric system based on a position where the modified version is measured in its passage.

### CROSS-REFERENCE TO RELATED APPLICATIONS

This application is a continuation-in-part of U.S. patent application Ser. No. 16/726,994, filed on 26 Dec. 2019, now allowed, which is a continuation of U.S. patent application Ser. No. 16/373,262, filed on 2 Apr. 2019 (now U.S. Pat. No. 10,557,885), which is a continuation of U.S. patent application Ser. No. 14/993,078, filed on 11 Jan. 2016 (now U.S. Pat. No. 10,288,666), which claims priority to U.S. Provisional Application No. 62/101,399, filed on 9 Jan. 2015. The entire disclosures of these applications are incorporated herein by reference.

### BACKGROUND

### Technical Field

Embodiments of the subject matter disclosed herein relate to detecting electrical faults in an electrical system of a vehicle.

### State of the Art

Modern vehicles include complex control systems and power systems that involve multiple components dispersed throughout the vehicle and extensive wiring interconnecting the components. In operation, a vehicle can experience significant vibration. Over time, wiring and other interconnections of the vehicle can wear due to reoccurring stresses. Deterioration of the wiring can introduce faults that prevent proper operation of the vehicle, or can lead to unexpected or unintended, and therefore, dangerous operation of the vehicle.

When an existence of a fault becomes known, service personnel may undertake a laborious effort of locating the fault. This process can involve manually testing, with leads, individual wires, circuits, or conductors to determine where the fault is located. Given the extensive amount of wiring, interconnections between wiring, electrical devices, and other electronic equipment present in the vehicle, the mere task of uncovering the problem can be time-consuming and expensive. This expense is additional to the cost of repairing or replacing the faulty component, once identified.

### BRIEF DESCRIPTION

In an embodiment, an electrical fault location detection system may include a fault location unit and a control unit. The control unit may electrically couple the fault location unit to an electrical system of a vehicle and trigger the fault location unit to conduct an electrical signal into the electrical system. When the electrical signal is conducted into the electrical system, the fault location unit provides information to the control unit indicative of a location of an electrical fault in the electrical system.

In an embodiment, a method for detecting a location of an electrical fault in a vehicle may include receiving, from a power system of the vehicle, a first signal indicative of an occurrence of an electrical fault in an electrical system of the vehicle. The method also may include triggering a fault locating circuit to conduct electrical signals to the electrical system of the vehicle. In addition, the method may include receiving from the fault locating circuit a second signal indicative of a location of the electrical fault in the electrical system. Further, the method can include outputting information relating to the location of the electrical fault in the electrical system to at least one of an operator of the vehicle or an entity remote from the vehicle.

In an embodiment, an electrical fault location detection system may include a control unit for a vehicle and a plurality of scan circuits in the vehicle. The control unit may electrically couple the plurality of scan circuits to an electrical system of the vehicle. The control unit may trigger the scan circuits to respectively conduct electrical signals into the electrical system of the vehicle. The respective scan circuits may detect a presence of an electrical fault in the electrical system based on the respective electrical signals. The scan circuits may provide information indicative of a location of the electrical fault in the electrical system, when detected, to the control unit.

In an embodiment, an electrical fault location detection system may include a fault location unit/system having plural scan circuits that are electrically connected to plural electrical circuits in an electrical system of a vehicle and configured to apply respective electrical signals to the plural electrical circuits. The system further may include a control unit configured for electrical communication with the plural scan circuits in the vehicle. The plural scan circuits may receive secondary signals respectively generated by the plural electrical circuits responsive to the electrical signals applied by the plural scan circuits to the plural electrical circuits and communicate information of the secondary signals that are received to the control unit. The control unit may determine a location of an electrical fault in the electrical system based on the information received from the plural scan circuits. The control unit may include control at least one electronic device based on the location of the electrical fault that is determined.

In an embodiment, an electrical fault location detection system may include at least one scan circuit on board a vehicle, a control unit, and a coupling circuit onboard the vehicle. The coupling circuit is electrically connected to the at least one scan circuit and to plural electrical circuits of an electrical system of the vehicle. The control unit may control the coupling unit to selectively electrically couple the at least one scan circuit to the plural electrical circuits. The at least one scan circuit is configured, while electrically coupled to the electrical circuits, to apply respective electrical signals to the plural electrical circuits and to receive secondary signals respectively generated by the plural electrical circuits responsive to the electrical signals. The at least one scan circuit may include communicate information of the received secondary signals to the control unit. The control unit may determine a location of an electrical fault in the electrical system based on the information received from the at least one scan circuit. The control unit may include control at least one electronic device based on the location of the electrical fault that is determined.

### BRIEF DESCRIPTION OF THE DRAWINGS

Reference is made to the accompanying drawings in which particular embodiments and further benefits of the invention are illustrated as described in more detail in the description below, in which:

FIG. 1 illustrates a schematic block diagram of an exemplary embodiment of a fault location system for a vehicle according to one or more aspects;

FIG. 2 illustrates a schematic block diagram of an exemplary embodiment of a control unit for a vehicle in accordance with one or more aspects;

FIG. 3 illustrates a schematic block diagram of an exemplary embodiment of vehicle components according to one or more aspects;

FIG. 4 illustrates a schematic block diagram of an exemplary embodiment of a fault location unit for a vehicle;

FIG. 5 illustrates a schematic block diagram of an exemplary embodiment of a scan circuit according to one or more aspects;

FIG. 6 illustrates a block diagram of an exemplary embodiment of a scan circuit schematically depicting structural and functional aspects of the scan circuit;

FIG. 7 illustrates a block diagram of an exemplary embodiment of a scan circuit schematically depicting structural and functional aspects of the scan circuit;

FIG. 8 illustrates a block diagram of an exemplary embodiment of a fault location unit for a vehicle in accordance with one or more aspects;

FIG. 9 illustrates a flow diagram of an exemplary embodiment of a method for locating a fault within an electrical system of a vehicle according to one or more aspects;

FIG. 10 illustrates a flow diagram of an exemplary embodiment of a method for identifying a location of a fault within an electrical system of a vehicle according to one or more aspects;

FIG. 11 is a wiring schematic of a fault location system, according to an embodiment; and

FIG. 12 is a wiring schematic of a fault location system, according to an embodiment.

### DETAILED DESCRIPTION

Embodiments described herein may relate to a system and method for locating an electrical fault in an electrical system that may be in a vehicle. The vehicle can include an extensive amount of wiring running throughout. In addition to the wiring, the vehicle may have numerous electrical interconnections, control lines, electrical devices, and/or other electronic devices that can be a cause of the electrical fault. Conventionally, narrowing down a location of the electrical fault can involve manually testing individual components (e.g., wire, interconnections, device) separately to pinpoint the cause or location of the fault. To test the components, service personnel may need gain physical access, which can pose safety risks to the personnel and be time-consuming. Accordingly, to merely locate a source of the electrical fault, portions and/or components of the vehicle may be disassembled to enable the test. By way of contrast, fault locating systems and methods described herein may reduce or eliminate some manual and laborious efforts to identify a source of an electrical fault. In addition, the fault locating systems and methods may reduce or eliminate a need to gain physical access prior to performing an actual repair of a faulty component. Accordingly, overall service time for electrical faults can be reduced.

The term vehicle can refer to various transportation systems. Suitable vehicles may include ground, air, and water vehicles. Suitable ground vehicles may include motor vehicles (e.g., motorcycles, automobiles, trucks, busses) and industrial vehicles. Suitable industrial vehicles may include rail vehicles, mining vehicles, agricultural vehicles, and construction vehicles. Suitable water vehicles may include marine vehicles, such as boats and ships. Suitable air vehicles may include aircraft (e.g., planes, rotorcrafts) and spacecraft. A rail vehicle may be a locomotive (freight or passenger), switcher, shunter, and the like. Suitable mining vehicles may include off-highway vehicles (such as large dump trucks), load, haul dump (LHD) vehicles, drilling rigs, and the like. In various embodiments, a suitable vehicle can be a single-compartment, permanently-arranged transportation system or a multiple-compartment, variably-arranged transportation system.

According to one or more aspects, a vehicle can include a control unit for monitoring and controlling various vehicle components. The control unit can be, for example, a microprocessor-based device having one or more processors and a memory for storing data and/or programs executed by the processor(s). The control unit can further include user interface devices to enable interactions with an operator of the vehicle and a communication device to enable communications with off-board devices or entities.

In a further aspect, the vehicle may include a power system having a power supply for providing electrical power to an electrical system of the vehicle. The power supply can include batteries, engines, generators, alternators, etc. that separately or jointly provide power to the electrical system. In this regard, the vehicle can include wiring, interconnections, and the like to couple the control unit to vehicle components for control and monitoring, but the vehicle can also include wiring, interconnections, and the like to couple the power supply to vehicle components for provisioning electrical power.

Herein, interconnections or wiring associated with control or data signals (i.e., the control system) can be described as separate from interconnections or wiring supplying electrical power (i.e., the electrical system or power system). Because the power that is driving the control or data signals of the control system is derived from the power supply, the control system (and the wiring and interconnections therein) can be considered to be a portion of the electrical system. The separate description of the control system from the power system is provided for convenience to describe modified techniques applicable to a control environment. Accordingly, the structures and techniques described herein with regarding to the electrical system of the vehicle may be employable with the wiring, interconnections, and devices of the control system.

As utilized herein, a vehicle component can refer to substantially any electrical or electronic component installed or included in a vehicle. For control aspect, a vehicle component can be any device having an embedded control unit. However, vehicle components can also include mechanical and/or electrical components, without embedded control or considered separate from associated embedded control units, such as engines, generators, alternators, electrical supply components (e.g., batteries), gauges, meters, communication equipment, lighting, sensors, switches, wiring harnesses, etc. Suitable vehicle components can include generators, alternators, rectifiers, engines, turbo chargers, cooling blowers, dynamic braking grids, inverters, converters, traction motors, etc. Suitable vehicle components are not limited to the aforementioned enumerated examples and encompass any electrical or electronic components which draw power from the power supply and/or can be controlled via the control unit.

In one or more embodiments, a fault location unit of a vehicle (which can be controlled or driven by a control unit of the vehicle in some embodiments) is provided to locate an electrical fault within an electrical system (or control system) of the vehicle. As utilized herein, the term electrical fault can include a change in current or a diversion along an unintended path. For instance, a diversion of current from a source path (e.g., positive or hot) to a return path (e.g., negative or neutral) is a short, which can be an electrical fault. A diversion of current to ground is a ground fault (e.g., another type fo electrical fault). These types of faults may be referred to as leakage currents. Other types of faults may include a change in resistance or electromagnetic interference (EMI) above a determine threshold level. EMI from nearby components and/or from failing EMI shielding.

The fault location unit can pass (e.g., conduct or inductively transfer) one or more electrical signals to (e.g., into) the electrical system, and on the basis of those electrical signals, identify a location of the electrical fault within the electrical system. Depending on a distribution of the electrical signals passed to the electrical system, the identified location can specify a particular circuit, cable, wire harness, vehicle component, vehicle system, or an individual wire or interconnect. The electrical signals can originate from (e.g., be generated by) circuits of the fault location unit. Alternatively, the electrical signals can be provided to the fault location unit from the control unit, for example. The electrical signals, while applied to the electrical system, generate secondary signals that can be analyzed to determine the location of the electrical fault. The secondary signals can be return signals or received signals that represent the originally passed signals modified by electrical paths of the electrical system. Under normal conditions, the secondary signals may exhibit a predetermined behavior. The presence of the electrical fault can cause deviations from the predetermined behavior. These deviations may be detected from measurements of the secondary signals. Accordingly, depending on a position within the electrical system where a secondary signal is measured and a position where a corresponding applied signal is passed, the location of the electrical fault can be determined.

The fault location unit can include one or more scan circuits respectively configured to apply an electrical signal to a portion of the electrical system, i.e., an electrical path of the electrical system. The electrical path, according to one or more aspects, can be a particular circuit, a particular length of wire, a cable including a plurality of individual wires, a wire harness, or a sub-system or sub-network of the electrical system. A secondary signal, received from or modified by the electrical path, can be returned to the scan circuit. According to one example, the scan circuit can include an evaluation circuit to compare the secondary signal to the applied signal (or some other reference) to determine a difference. When the difference exceeds a threshold, unintended diversion of current can be a cause. Accordingly, when the threshold is exceeded, the scan circuit emits a detection signal indicating a presence of an electrical fault on the electrical path. In another example, the secondary signal can be provided to the control unit for evaluation.

The scan circuit can include a pair of circuits or cells, where a first cell applies the signal to the electrical path and the second cell receives the return, response, or secondary signal. The first cell and the second cell can jointly operate to implement the evaluation circuit. Alternatively, the second cell can include a dedicated circuit implementing the evaluation functionality.

In an aspect, the fault location unit can include a plurality of scan circuits which are designated to predetermined portions or electrical paths of the electrical system. In this regard, an identity of the particular scan circuit that reports detection of the electrical fault provides the location information. Depending on a number of scan circuits provided and a level to which the electrical system is partitioned or segmented for the purposes of assignment to scan circuits, the location information can be provided at a sub-system level, a circuit level, a cable level, or an individual wire or interconnect level. For example, a scan circuit can be provided to each wire or interconnect of the electrical system. Alternatively, one or more scan circuits can be selectively, and separately, coupled to different wires, circuits, or interconnects so as cycle and test each individually.

The fault location unit, and particularly the scan circuits thereof, can be isolated from the electrical system when not in use. A coupling circuit can maintain the fault location unit in isolation until the electrical fault occurs. At that time, the coupling circuit can electrically couple the fault location unit to the electrical system to enable operation. As utilized herein, the term electrically couple can refer to establishing a connection that enables at least one of information or a signal to pass, either with or without any sort of physical coupling or contact.

According to an additional aspect, the power supply can include a sensor configured to detect an occurrence of the electrical fault within the electrical system as a whole. This information can be provided to the control unit for initiation of self-testing (e.g., self-locating) for the electrical fault. Further, the control unit can display a warning or other information related to the electrical fault on a display device for an operator of the vehicle. The control unit can signal for the fault location unit to be coupled to the electrical system and, further, can trigger the fault location unit to begin diagnosing the electrical system. The fault location unit can be triggered in response to a user input received from the operator via a user interface.

Prior to triggering the fault location unit, the control unit can determine whether the vehicle is in a safe state. The safe state can include any state of the vehicle in which spurious signals, currents, or voltages applied to the electrical system are tolerated and will not cause a dangerous situation or result. By way of example, while in a safe state, the vehicle will not behave erratically or unexpectedly should the signal applied by the fault location unit be interpreted as a throttle signal, for example. Suitable safe states can include an idle state, a stationary state, a tie-down state (e.g., brakes applied), a disassembled or pre-assembly state, deenergized state, or the like.

Once provided with information related to the location of the electrical fault, the controller can output such information to the display device and/or communicate the information to an entity remote from the vehicle. An entity that is remote from the vehicle can be a computing device which is not physically or conductively coupled to the vehicle. The entity may not be limited to being geographically or physically remote from the vehicle. For instance, in one embodiment, the entity can be a mobile device carried by the operator or other service personnel aboard the vehicle. In other embodiments, the entity can be a computing device at a service location, a storage location, or some other vehicle station.

According to one embodiment, a system for locating electrical faults is described. The system may include a fault location unit and a control unit. The control unit may electrically couple the fault location unit to an electrical system of a vehicle and to trigger the fault location unit to pass an electrical signal to the electrical system. When the electrical signal is passed to the electrical system, the fault location unit provides information to the control unit indicative of a location of an electrical fault in the electrical system.

According to one example, the system can include a sensor for detecting an occurrence of the electrical fault in the electrical system. The sensor may send a signal indicative of the occurrence of the electrical fault to the control unit when detected. The system further may include a power supply configured to provide electrical power to the electrical system of the vehicle. The sensor can be coupled to the power supply.

In another example, the control unit may verify the vehicle is in a safe state prior to electrically coupling the fault location unit to the electrical system. According to another example, the system may include a coupling circuit configured, in a first mode of operation, to selectively couple the fault location unit to the electrical system, and in a second mode of operation to isolate the fault location unit from the electrical system.

According to one example, the fault location unit may include a scan circuit configured to pass a signal to an electrical path of the electrical system to detect a presence of the electrical fault in the electrical path to which the scan circuit is coupled. The scan circuit can include an evaluation circuit to compare the signal transmitted on the electrical path to a signal later received on the electrical path. The evaluation circuit may output a detection signal when a difference in the signal transmitted and the signal received exceeds a threshold.

The scan circuit, according to some examples, may include a first cell and a second cell. The first cell may pass the electrical signal on the electrical path and the second cell may receive the electrical signal on the electrical path. In one example, the electrical path can be a circuit such that the first cell transmits the electrical signal on a first wire and the second cell receives the electrical signal on a second wire that completes the circuit. In another example, the electrical path is a length of wire such that the first cell transmits the electrical signal on the length of wire to the second cell.

The fault location unit can be configured to individually and cyclically couple the scan circuit to a plurality of portions of the electrical system to test each portion for the electrical fault.

Further, the control unit can include a user interface device having at least a display device configured to display information to an operator of the vehicle and a communication interface configured to communicate with an entity remote from the vehicle. The control unit can be configured to at least one of output the information indicative of the location of the electrical fault in the electrical system to the display device, or transmit the information, via the communication interface, to an entity remote from the vehicle.

According to another embodiment, a method for locating an electrical fault is described. The method may include receiving, from a power system of a vehicle, a signal indicative of an occurrence of an electrical fault in an electrical system of the vehicle. The method also may include triggering a fault locating circuit to pass electrical signals to the electrical system of the vehicle. In addition, the method may include receiving, from the fault locating circuit, a signal indicative of a location of the electrical fault in the electrical system. Further, the method may include outputting information relating to the location of the electrical fault in the electrical system to at least one of an operator of the vehicle or an entity remote from the vehicle.

In accordance with an example, the method may include electrically coupling the fault locating circuit to the electrical system of the vehicle in response to the signal indicative of the occurrence of the electrical fault from the power system, and otherwise isolating the fault locating circuit from the electrical system. In further examples, the method can include determining a state of the vehicle, and verifying the state of the vehicle is a safe state prior to triggering the fault locating circuit.

In yet another example, the method can include passing a signal to an electrical path of the electrical system to detect a presence of the electrical fault in the electrical path. In addition, the method may include comparing the signal transmitted on the electrical path to a signal received on the electrical path, determining when a difference in the signal transmitted and the signal received exceeds a threshold, and issuing the signal indicative of the location of the electrical fault when the threshold is exceeded. The location indicated by the signal specifies the electrical path.

In yet another embodiment, a system is described that may include a control unit for a vehicle and a plurality of scan circuits in the vehicle. The control unit may electrically couple the plurality of scan circuits to an electrical system of the vehicle and trigger the plurality of scan circuits to respectively pass a plurality of electrical signals to the electrical system of the vehicle. Moreover, respective scan circuits of the plurality of scan circuits are respectively configured to detect a presence of an electrical fault in the electrical system based on respective electrical signals of the plurality of electrical signals. The respective scan circuits are further configured to provide information indicative of a location of the electrical fault in the electrical system, when detected, to the control unit.

According to an example of the foregoing embodiment, respective scan circuits of the plurality of scan circuits respectively comprise a pair of circuits configured to pass a test signal to a designated portion of the electrical system and receive a response signal from the designated portion of the electrical system. The pair of circuits output a detection signal to the control unit when a difference between the test signal and the response signal exceeds a threshold. The control unit determines the location of the electrical fault based on the designated portion of the electrical system associated with the pair of circuits which output the detection signal.

With reference to the drawings, like reference numerals designate identical or corresponding parts throughout the several views. However, the inclusion of like elements in different views does not mean a given embodiment necessarily may include such elements or that all embodiments of the invention include such elements.

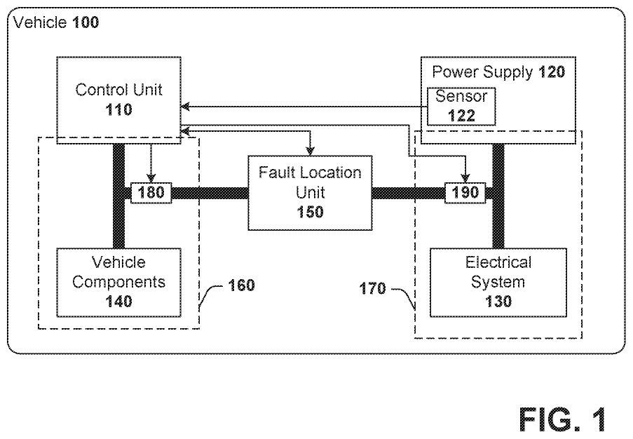

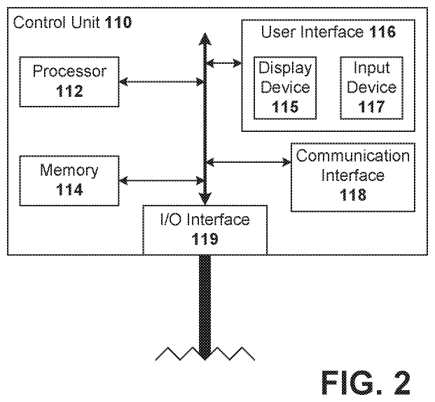

Turning to FIG. 1, illustrated is a schematic block diagram of an exemplary embodiment of a fault location system for a vehicle 100. In the embodiment, the vehicle may have a controller or control unit 110 for controlling and monitoring vehicle components 140 via a control path 160. As shown in FIG. 2, the control unit may include a processor 112, a memory 114, a user interface, a communication interface 118, and an I/O interface 119. The user interface can include a display device 115 to output information to an operator of the vehicle and an input device 117 to obtain information from the operator. A suitable display device can be a display screen, a segment display, and a series of graphical elements. Suitable elements can be illuminated, and may include gauges, meters, and the like. The input device can include keyboards, pointing devices, buttons, switches, knobs, dials, and the like. The display device and the input device can be contained within a single device (e.g., touch screen) such that user interface has a graphical user interface generated by the processor based on computer-executable instructions (e.g., a control application) stored on memory.

A control unit can be selected to communicate via a wired or wireless medium. If wired, the communication interface can enable the control unit to communicate via a cable, e.g., USB cable, serial cable, Ethernet cable, and the like. If wireless, the control unit may communicate via WiFi (e.g., IEEE 802.11), cellular radio (e.g., GSM, LTE, CDMA, HSPA, UMTS, WiMAX, etc.), satellite communication, near-field communication, infrared, a short-range radio frequency (RF) protocol such as Bluetooth, or another wireless communication technology selected based on the end use requirements.

The I/O interface may include the external connectors to couple the control unit to the control path to enable communication with the vehicle components. The I/O interface may include the internal interconnections, adapters, and circuits to couple to the processor. The I/O interface can transform signals or data from a format suitable for processing by the control unit to a format suitable for transmission via the control path and/or a format suitable for consumption by the vehicle components. Likewise, the I/O interface can perform a complementary transformation on incoming data or signals.

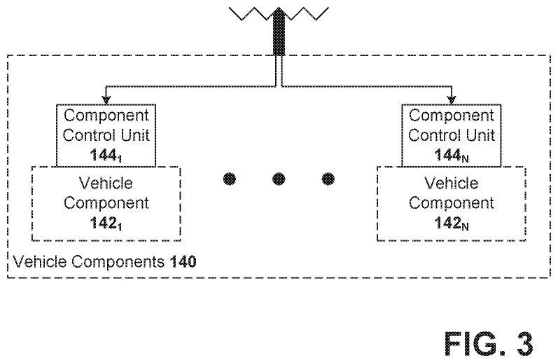

Turning to FIG. 3, the vehicle components can include one or more individual vehicle components 142 (depicted as vehicle components 142₁ through 142_{N}, where N is any integer greater than or equal to one), such as various electrical, mechanical, or control components. A suitable vehicle component can include a corresponding component control unit 144. The control unit may be an endpoint on the control path.

The vehicle may include a power supply 120. The power supply may provide electrical power to an electrical system 130 via an electrical supply path 170. As described above, the electrical system and the electrical supply path include, in some embodiments, the control path, the vehicle component and the wires, interconnections, etc. of the control path. That is, when discussing the electrical system, it is intended to include the control path and the vehicle components, unless explicitly stated otherwise.

As shown in FIG. 1, a sensor 122 may detect an occurrence of an electrical fault in the electrical system. According to one example, the sensor can be coupled to or included in the power supply. The sensor can register a voltage drop, for example, or measure a return current to determine whether any unintended diversion of current is occurring within the electrical system. Once the electrical fault is detected, the sensor can send a signal to the control unit.

The control unit, can output a notification of the electrical fault to the user interface in response to the signal from the sensor. The control unit may initiate a self-testing routine to locate the electrical fault. According to one example, the self-testing can commence autonomously upon receiving the signal from sensor. In another example, user input via user interface may begin self-testing.

To initiate self-testing, the control unit electrically couples a fault location unit 150 to the electrical system. For instance, the control unit can pass signals to coupling circuits 180, 190 to electrically couple the fault location unit to the electrical supply path and/or the control path, thereby attaching the fault location unit to the electrical system. The coupling circuits may electrically isolate the fault location unit from the electrical system except when the signal is passed from the control unit.

Once coupled, the fault location unit can be brought on-line by the control unit. Once activated, the fault location unit can apply electrical signals to the electrical system to identify a location of the electrical fault therein. Once identified, the fault location unit provides location information to the control unit. The location information can be displayed on a display screen of the user interface and/or transmitted to an entity remote from the vehicle via the communication interface.

Prior to triggering the fault location unit, the control unit can determine a state of the vehicle. For instance, the control unit, via the control path, can interrogate the vehicle components to ascertain current statuses thereof. In another example, the control unit, which can receive regular streams of information from the vehicle components, can determine the state based on data stored in memory. In addition, the control unit can determine the state the based at least in part on a snapshot of a stream of data. Once the state of the vehicle is identified, the control unit may trigger or signal to the fault location unit when the vehicle is in a safe state.

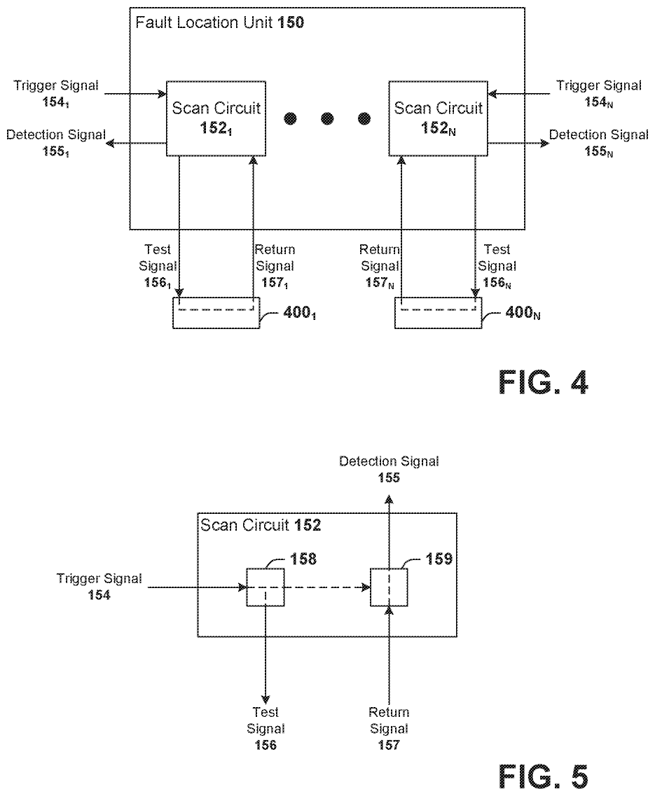

Turning to FIG. 4, illustrated is a schematic block diagram of an exemplary embodiment of the fault location unit. As shown in FIG. 4, the fault location unit can include one or more scan circuits 152 (depicted as scan circuit 152.sub.1 through scan circuit 152.sub.N, where N is any integer greater than or equal to one). Each scan circuit may receive a trigger signal 154. The signal may come from the control unit for example. The control unit may initiate a test procedure for at least a portion of the electrical system.

For the test procedure, the scan circuit applies a test signal 156 to an electrical path 400 of the electrical system. The electrical path can be an individual wire, an individual electrical component, a circuit, a portion of a circuit, a sub-system, and the like. In response, the scan circuit receives a secondary signal or return signal 157, which represents the test signal as modified by the electrical path. The scan circuit can evaluate the return signal to determine whether the electrical fault is present on the electrical path. If so, the scan circuit sends a detection signal 155 to the control unit.

According to an aspect, each scan circuit can be associated with a particular respective portion of the electrical system (e.g., a particular wire, interconnection, circuit or portion thereof). As such, the detection signal indicates a location of the electrical fault. The detection signal from a given scan circuit indicates the electrical fault may be located in the portion of the electrical system associated therewith.

FIG. 5 illustrates a schematic block diagram of an exemplary embodiment of the scan circuit according to one or more aspects. The scan circuit can include a pair of circuits 158, 159, which are also referred to herein as a first cell 158 and a second cell 159. The pair of circuits may pass the test signal to a designated electrical path of the electrical system, receive the return signal from the electrical path, and evaluate the return signal to determine whether the electrical fault is located on the electrical path.

The first cell can receive the trigger signal from the control unit and, in response, apply the test signal to the electrical path. According to one example, the test signal can be generated by the circuit implementing the first cell. In another example, the control unit can generate the test signal and the first cell can pass the test signal through to the electrical path. For instance, the trigger signal 154 can be the test signal, with or without modification by the first cell.

The second cell can receive the secondary or return signal from the electrical path. The second cell may include an evaluation circuit which analyzes the return signal to determine whether the electrical fault exists on the electrical path. In one example, the evaluation circuit can compare the test signal to the return signal to determine a difference. The difference can be measured against a threshold that, when exceeded, triggers the second cell to emit the detection signal. According to another example, the second cell can merely pass through the return signal to the control unit, which evaluates the signal to determine whether the electrical fault exists on the electrical path associated with the scan circuit. For instance, a diagnostic application or program stored on memory can be executed by processor to generate trigger signal (and/or test signal) and analyze the detection signal (and/or return signal).

Depending on the electrical path being tested, the first cell and the second cell can be implemented in a variety of manners providing different structural or functional aspects. Moreover, in the case of an electrical path associated with the control path, at least one of the first cell or the second cell can be associated with, coupled to, or included in the component control unit.

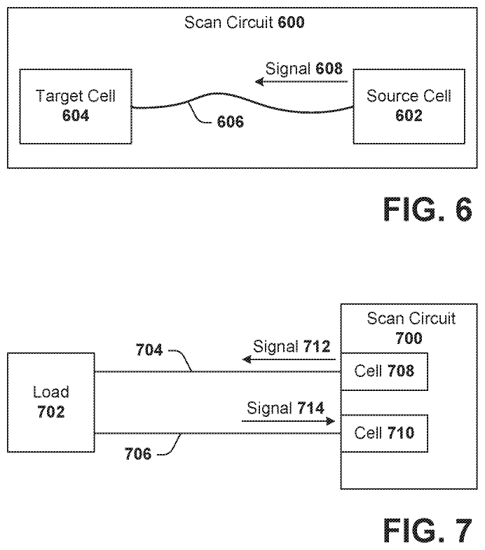

Turning to FIG. 6, illustrated is a block diagram of an exemplary embodiment of a scan circuit 600 for testing a wire or interconnection, according to an aspect. The scan circuit may include a source cell 602 and a target cell 604 electrically coupled by a wire or interconnection 606. The source cell applies a signal 608 (i.e., a test signal) to the wire, which is received by the target cell. The signal can be evaluated by the target cell, or passed to a control system for evaluation, to determine whether an electrical fault is present along wire.

In an example, the source cell 602 can be associated with the fault location unit or control unit 110 and the target cell 604 can be associated with the component control unit. The source cell 602 can be positioned at one terminal or boundary of the wire 606, which can be, for example, physically proximal to the control unit or power supply 120. The target cell 604 can be positioned at another terminal or boundary of the wire 606 at a location physically remote from the control unit or power supply.

FIG. 7 illustrates a block diagram of an exemplary embodiment of a scan circuit 700 for testing a circuit for an electrical fault, according to an aspect. Scan circuit is electrically coupled to a circuit or load 702 having a positive or hot wire and a negative or neutral wire 706. The scan circuit may include a first cell 708 that applies a first signal 712 on the positive wire and a second cell 710 that receives a second signal 714 on the negative wire. The second signal can be analyzed to determine whether an electrical fault is present in the circuit or load, positive wire, or negative wire.

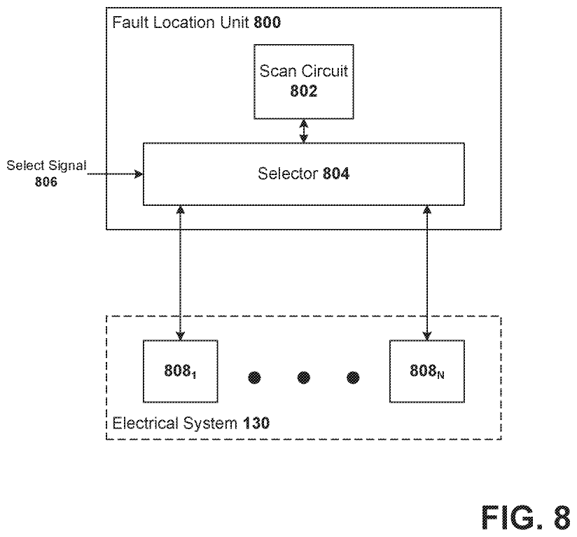

FIG. 8 illustrates a block diagram of an exemplary embodiment of a fault location unit 800 unit is provided. The fault location unit may include a scan circuit 802 and a selector 804. The scan circuit may be similar to and perform substantially similar functionality as the scan circuits described above.

The scan circuit 802 may be coupled to an input of the selector. The selector may be a multiplexor or other routing circuit configured to selectively couple the input to one of a plurality of outputs. The output of the plurality of outputs is determined by a select signal 806. The select signal can be generated by the fault location unit itself, or externally provided by a control unit for example. The plurality of outputs of the selector are respectively coupled, electrically, to one or more portions or electrical paths 808 of the electrical system (designated as electrical path 808.sub.1 through electrical path 808.sub.N, where N is any integer greater than or equal to one). By varying the select signal, the fault location unit can cycle through the electrical paths and test each one, individually, with the scan circuit.

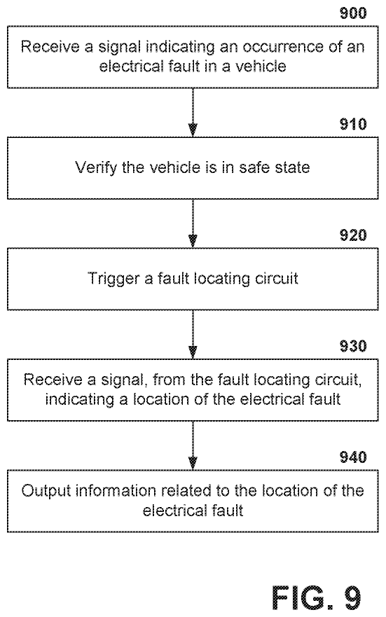

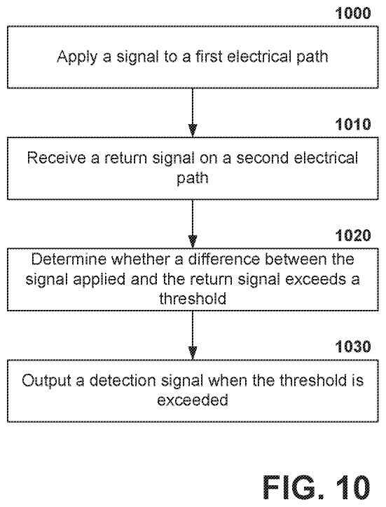

In view of the exemplary devices and systems described, methodologies that can be implemented in accordance with the disclosed subject matter are described with reference to the flow charts of FIGS. 9 and 10. The methodologies can be implemented by the system described above with respect to FIGS. 1-8, for example.

FIG. 9 illustrates a flow diagram of an exemplary embodiment of a method for locating a fault within an electrical system of a vehicle according to one or more aspects. At step 900, a signal indicating an occurrence of an electrical fault in a vehicle is received. The signal can be generated by a sensor, for example, coupled to a power supply of the vehicle. At step 910, it is verified that that vehicle is in a safe state. A control until of the vehicle, based on information or signals from various vehicle components, can determine a state of the vehicle. At step 920, a fault locating circuit is triggered. In an example, the fault locating circuit can be electrically isolated from the electrical system of the vehicle, but electrically coupled to the electrical system in response to the signal received at step 900. In another example, the fault locating circuit can be electrically coupled to the electric system of the vehicle, but electrically isolated from the electric system in response to the signal received. At step 930, a signal is received from the fault locating circuit. The signal indicates a location of the electrical fault in the electrical system of the vehicle. At step 940, the information related to the location of the electrical fault is output. For example, the information can be output to a display screen of a user interface or communicated, via a communication interface, to an entity remote from the vehicle.

FIG. 10 illustrates a flow diagram of an exemplary embodiment of a method for identifying a location of a fault within an electrical system of a vehicle according to one or more aspects. At step 1000, a signal is applied to a first electrical path. According to an example, the signal is provided by a scan circuit having a pair of cells, which is designated to the first electrical path. At step 1010, a return signal is received on a second electrical path. The first and second electrical paths can be a same path, or different paths. For example, when testing an individual length of wire, the first and second paths can be the same individual length of wire. Alternatively, when testing the individual length, the first electrical path can be the length of wire, while the second electrical path is another wire, wires, or circuit. Further still, when testing a circuit, for example, the first path can be a first set of wires (e.g., one or more wires) and the second path can be a second set of wires (e.g., one or more wires) that completes the circuit. In some embodiment or examples, the second electrical path can be known to be fault-free, such that the first electrical path is the portion under test. At step 1020, it is determined, on the basis of the return signal, whether an electrical fault is present on the electrical path (e.g., either the first electrical path or second electrical path). For example, the signal applied and the return signal can be compared to determine whether a difference therebetween exceeds a threshold. At step 1030, when determined that an electrical fault is present (e.g., the threshold is exceeded), a detection signal is output. The method may compute a difference signal and comparing said signal to a threshold is one exemplary technique to detect an electrical fault. Other techniques may be applicable and are contemplated within the bounds of the claimed subject-matter unless explicitly detailed otherwise.

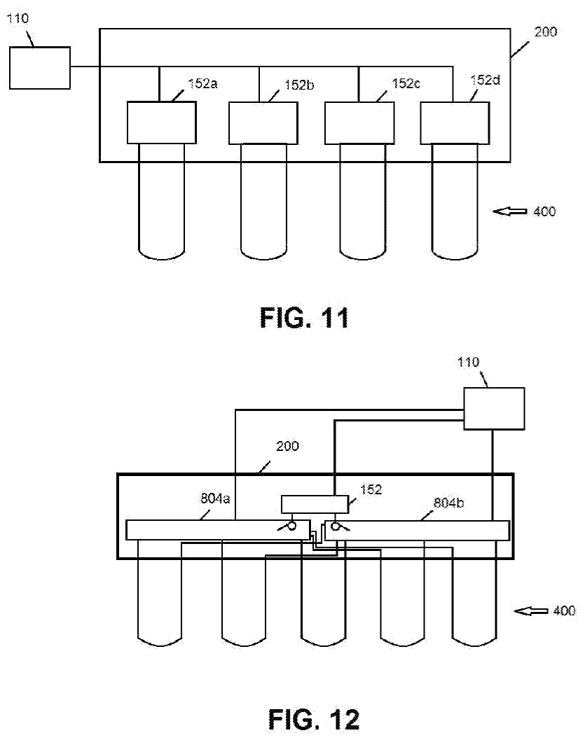

FIG. 11 shows a wiring schematic of an embodiment of the fault location system. In particular, as illustrated, for each circuit of interest (e.g., each circuit may be a wire loop/circuit) in the vehicle electrical system, a separate and distinct scan circuit 152a, 152b, 152c, 152d, etc. is respectively connected to the circuit of interest. In one embodiment, the connection is in parallel. That is, in this embodiment, there is a scan circuit for each wire or other circuit portion of interest. In a given electrical system, this may mean the provision of hundreds or thousands of scan circuits. However, with mass produced, low cost micro-electronics currently available on the market, implementations on such a scale may nevertheless be practicable. Suitable scan circuits can be built into the electrical panels, circuit boards, etc. to which the wire loops or other circuits are part of and/or electrically coupled, keeping implementation costs relatively low.

FIG. 12 shows a wiring schematic of another embodiment of the fault location system. Here, the system may include one scan circuit and a pair of selector units (e.g., multiplexers) 804a, 804b. The control unit may control the selector units 804a, 804b, one for selectively connecting the out path of each circuit to the scan circuit and the other for selectively connecting the in path of each circuit to the scan circuit. The scan circuit is cyclically connected to the circuits for testing each in turn.

In an embodiment, a system (e.g., an electrical fault location detection system) may include plural scan circuits respectively electrically connected to plural electrical circuits in an electrical system of a vehicle and configured to apply respective electrical signals to the plural electrical circuits. The system further may include a control unit configured for electrical communication with the plural scan circuits in the vehicle. (The control unit may be located off board the vehicle, in which case the control unit may be configured to wirelessly communicate with the scan circuits on board the vehicle; in one embodiment, however, the control unit is located on board the vehicle and is electrically connected to the scan circuits either wirelessly or with wires.) The plural scan circuits are further configured to receive secondary signals respectively generated by the plural electrical circuits responsive to the electrical signals applied by the plural scan circuits to the plural electrical circuits, and to communicate information of the secondary signals that are received to the control unit. The control unit may determine a location of an electrical fault in the electrical system based on the information received from the plural scan circuits. The control unit may include control at least one electronic device based on the location of the electrical fault that is determined.

For example, in an embodiment, the at least one electronic device that the control unit may control comprises (i) a display device of a user interface of the vehicle, for display of the location of the electrical fault in the electrical system, and/or (ii) a communication device, for communication of the location of the electrical fault in the electrical system to a device off board the vehicle. In another embodiment, the at least one electronic device that the control unit may control comprises a vehicle system on board the vehicle. For example, the control unit may be configured to control the electrical system of the vehicle, an engine of the vehicle or another component of a propulsion system of the vehicle, etc., for operation from a first state to operation in a different, second state, such as the vehicle being brought from moving along a route to a stopped condition, or the electrical system (or portion thereof) being transitioned from an on or operational state to an off or non-operating state.

In an embodiment, the control unit may generate control signals for communication to the plural scan circuits, and the scan circuits are configured to apply the electrical signals to the plural electrical circuits responsive to the control signals. In an embodiment, the system further may include a sensor configured to detect an occurrence of the electrical fault in the electrical system. The sensor may include send a signal indicative of the occurrence of the electrical fault to the control unit when detected, and the control unit may generate the control signals responsive to receipt of the signal indicative of the occurrence of the electrical fault. For example, the vehicle may include a power supply configured to provide electrical power to the electrical system of the vehicle, and in such an instance the sensor may be coupled to the power supply for detecting the electrical fault based on a change in electrical power output by the power supply (for example). In an embodiment, the scan circuits are configured to be selectively electrically coupled to the plural electrical circuits, and to electrically couple to the plural electrical circuits responsive to the control signals. For example, the scan circuits may be connected to the vehicle electrical circuits by respective switches, which the control unit may control with the control signals. In an embodiment, the control unit may verify the vehicle is in a designated operational state (e.g., a safe state, such as stopped at a designated location) as a condition precedent for generating the control signals to electrically couple the scan circuits to the electrical system.

In an embodiment, the system further may include a coupling circuit (e.g., one or more multiplexer circuits) configured, in a first mode of operation under control of the control unit, to selectively couple the scan circuits to the electrical system, and in a second mode of operation under control of the control unit to isolate the scan circuits from the electrical system. In an embodiment, the scan circuit may include an evaluation circuit that may determine a comparison of the respective one of the electrical signals applied to the electrical circuit (the electrical circuit to which the scan circuit is electrically connected) to a respective one of the secondary signals generated by the electrical circuit responsive to the respective one of the electrical signals applied to the electrical circuit, and the evaluation circuit may be configured to output a detection signal based on the comparison, the detection signal including the information communicated to the control unit.

In an embodiment, the scan circuit further may include a first cell and a second cell. The first cell may apply the respective one of the electrical signals to a first wire of the electrical circuit. The second cell may receive the respective one of the secondary signals on a second wire of the electrical circuit that completes the electrical circuit. In an embodiment, the scan circuit may include a first cell and a second cell, and the electrical circuit comprises a length of wire. The first cell may apply the respective one of the electrical signals on the length of wire, and the second cell may receive the respective one of the secondary signals on the length of wire. In an embodiment, a system (e.g., an electrical fault location detection system) may include at least one scan circuit on board a vehicle, a control unit, and a coupling circuit (e.g., one or more multiplexer circuits) on board the vehicle. The coupling circuit is electrically connected to the at least one scan circuit and to plural electrical circuits of an electrical system of the vehicle. The control unit may control the coupling unit to selectively electrically couple the at least one scan circuit to the plural electrical circuits. The at least one scan circuit is configured, when electrically coupled to the electrical circuits, to apply respective electrical signals to the plural electrical circuits and to receive secondary signals respectively generated by the plural electrical circuits responsive to the electrical signals. The at least one scan circuit may include communicate information of the secondary signals that are received to the control unit. The control unit may determine a location of an electrical fault in the electrical system based on the information received from the at least one scan circuit. The control unit may include control at least one electronic device based on the location of the electrical fault that is determined.

In an embodiment, a system (e.g., an electrical fault location detection system) may include at least one scan circuit on board a vehicle, a control unit, and a coupling circuit (e.g., multiplexer circuit) on board the vehicle. The coupling circuit is electrically connected to the at least one scan circuit and to plural electrical circuits of an electrical system of the vehicle. The control unit may control the coupling unit to selectively electrically couple the at least one scan circuit to the plural electrical circuits. The at least one scan circuit is configured, when electrically coupled to the electrical circuits, to apply respective electrical signals to the plural electrical circuits and to receive secondary signals respectively generated by the plural electrical circuits responsive to the electrical signals. The at least one scan circuit may include communicate information of the secondary signals that are received to the control unit. The control unit may determine a location of an electrical fault in the electrical system based on the information received from the at least one scan circuit. The control unit may include control at least one electronic device based on the location of the electrical fault that is determined, and to control the coupling circuit to individually and cyclically couple a single one of the at least one scan circuit to the plural electrical circuits to test each of the plural electrical circuits for the electrical fault. (That is, one scan circuit is connected to an individual electrical circuit for testing, and is then disconnected from that circuit for re-connection to another electrical circuit, and so on until all circuits are tested.) Further, the at least one electronic device that the control unit may control may include a vehicle system on board the vehicle.

In an embodiment, a system (e.g., an electrical fault location detection system) may include at least one scan circuit on board a vehicle, a control unit, a coupling circuit (e.g., multiplexer circuit) on board the vehicle, and a sensor configured to detect an occurrence of the electrical fault in the electrical system. The coupling circuit is electrically connected to the at least one scan circuit and to plural electrical circuits of an electrical system of the vehicle. The control unit may control the coupling unit to selectively electrically couple the at least one scan circuit to the plural electrical circuits. The at least one scan circuit is configured, when electrically coupled to the electrical circuits, to apply respective electrical signals to the plural electrical circuits and to receive secondary signals respectively generated by the plural electrical circuits responsive to the electrical signals. The at least one scan circuit may include communicate information of the secondary signals that are received to the control unit. The control unit may determine a location of an electrical fault in the electrical system based on the information received from the at least one scan circuit. The control unit may include control at least one electronic device based on the location of the electrical fault that is determined. The sensor may send a signal indicative of the occurrence of the electrical fault to the control unit when detected, and the control unit may control the coupling unit to electrically couple the at least one scan circuit to the plural electrical circuits responsive to receipt of the signal indicative of the occurrence of the electrical fault.

The terms controller, control unit, control system, or control device can refer to device that is capable of controlling the actions of another component or device. Examples range from a simple switching device, through devices having one or more processors running computer-executable software instructions, to complex programmable and/or non-programmable logic circuitry. The terms signal, data, and information can be used interchangeably herein and can be in digital or analog form. The terms software, computer program, or program include, but are not limited to, one or more computer-readable and/or executable instructions that cause a computer or other electronic device to perform functions, actions, and/or behave in a desired manner. The form of hardware and software may depend at least in part on the requirements of a desired application, an environment the software executes in, and/or desires of a designer/programmer. The terms computer, processing device, computing device, or processor may include a programmed or programmable device that can store, retrieve, and process data. Non-transitory computer-readable media include, but are not limited to, a CD-ROM, a removable flash memory card, a hard disk drive, a magnetic tape, and a floppy disk. Computer memory or memory, as used herein, can refer to a storage device configured to store digital data or information which can be retrieved by a computer or processing element.

In the specification and claims, the singular forms a, an, and the include plural referents unless the context clearly dictates otherwise. Approximating language, as used herein throughout the specification and claims, may be applied to modify a quantitative representation that could permissibly vary without resulting in a change in the basic function to which it is related. Accordingly, a value modified by a term such as about is not to be limited to the precise value specified. In some instances, the approximating language may correspond to the precision of an instrument for measuring the value. Moreover, unless specifically stated otherwise, a use of the terms first, second, etc., do not denote an order or importance, but rather the terms first, second, etc., are used to distinguish one element from another.

As used herein, the terms may and may be indicate a possibility of an occurrence within a set of circumstances; a possession of a specified property, characteristic or function; and/or qualify another verb by expressing one or more of an ability, capability, or possibility associated with the qualified verb. Accordingly, usage of may and may be indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity cannot occur—this distinction is captured by the terms may and may be.

This written description uses examples to disclose the invention, including the best mode, and also to enable one of ordinary skill in the art to practice the invention, including making and using a devices or systems and performing incorporated methods. The patentable scope of the invention is defined by the claims, and may include other examples that occur to one of ordinary skill in the art. Such other examples are intended to be within the scope of the claims if they have structural elements that do not differentiate from the literal language of the claims, or if they include equivalent structural elements with insubstantial differences from the literal language of the claims.

What is claimed is:

1. A system comprising:
a location unit that is configured to direct one or more distributions of electrical signals through different conductive pathways of a plurality of conductive pathways and therethrough to plural components of an electric system,
the location unit being further configured to receive a modified version of one or more of the electric signals, and the distributed one or more electric signals is changed into the modified version by its passage through the one or more of the conductive pathways, and
the location unit being configured to determine a location of an electric fault in the electric system based on a position where the modified version is measured in its passage through the one or more conductive pathways; and
a coupling unit that is configured to couple the location unit to the electrical system.

2. The system of claim 1, wherein the location unit includes plural scan circuits each configured to direct a subset of the distribution of the electric signals into a different portion of the electric system and determine the location of the electric fault within the corresponding portion of the electric system.

3. The system of claim 1, wherein the location unit is further configured to determine the location of the electric fault by comparing at least one of the electric signals in the distribution with the modified version of the one or more electric signals.

4. The system of claim 1, wherein the location unit is further configured to direct the distribution of the electric signals through the conductive pathways that are used to conduct control signals to the electric system of a vehicle for control of movement of the vehicle.

5. The system of claim 4, wherein the coupling unit is further configured to selectively couple the location unit to the electric system of the vehicle under control of a control unit and based at least in part on an operating state of the vehicle.

6. The system of claim 4, wherein the control unit is further configured to prevent the location unit from directing the distribution of the electrical signals through the conductive pathways unless the vehicle is in a state where the distribution of the electric signals does not change a movement of, or cause the movement of, the vehicle.

7. The system of claim 1, wherein the location unit is configured to determine the location of the electric fault in one or more of a wire, a wire interconnect, a wire harness, a cable, a circuit, or one of the components of the electric system.

8. The system of claim 1, wherein the coupling unit comprises a multiplexer circuit.

9. A method comprising:
distributing plural electrical signals through different conductive pathways to several components of an electric system;
receiving a modified version of one or more of the electric signals, wherein the one or more electric signals is changed into the modified version by its passage through one or more of the conductive pathways;
determining a location of an electric fault in the electric system based on a position where the modified version is measured in its passage through the one or more conductive pathways.

10. The method of claim 9, wherein the distribution of the electric signals is directed through the conductive pathways that are used to conduct control signals to the electric system of a vehicle for control of movement of the vehicle.

11. The method of claim 9, wherein the location of the electric fault is determined by comparing at least one of the electric signals in the distribution with the modified version of the one or more electric signals.

12. The method of claim 9, wherein directing the distribution of electric signals into the electric system includes directing a subset of the distribution of the electric signals into each of plural, different portions of the electric system and determining the location of the electric fault within at least one of the portions of the electric system.

13. The method of claim 9, further comprising preventing a location unit that generates the distribution of the electric signals from generating the electric signals unless the vehicle is in a state where the distribution of the electric signals does not change or cause movement of the vehicle.

14. The method of claim 9, further comprising:
isolating a location unit that generates the distribution of the electrical signals from the electric system where the modified version of the one or more electric signals indicates the electric fault.

15. A location unit configured to:
direct electrical signals through different conductive pathways to several components of an electric system, wherein the conductive pathways are configured to modify the electric signal in response to a change in state of the conductive pathway and thereby to create a modified version of the one or more electric signals,
receive the modified version of one or more of the electric signals, and
determine a location of an electric fault in the electric system based at least in part on a difference between (a) at least one of the electric signals and (b) the modified version of the one or more electric signals.

16. The system of claim 15, wherein the location unit is configured to determine the location of the electric fault also based on a measurement position where the modified version of the one or more electric signals is measured and an application position where the one or more electric signals that is changed into the modified version.

17. The system of claim 15, wherein the location unit is configured to direct the electric signals through the conductive pathways that are used to conduct control signals to the electric system of the vehicle for control of movement of a vehicle, and further comprising
a control unit that is configured to prevent the location unit from directing the electrical signals through the conductive pathways unless the vehicle is in a state where the electric signals do not change or cause movement of the vehicle; and a coupling unit under control of the control unit and configured to electrically couple the location unit to the electric system of the vehicle.

18. The system of claim 15, wherein the location unit includes plural scan circuits each configured to direct a subset of the electric signals into a different portion of the electric system and determine the location of the electric fault within the corresponding portion of the electric system.

19. The system of claim 18, wherein the location unit is configured to determine the location of the electric fault in one or more of a wire, a wire interconnect, a wire harness, a cable, a circuit, or one of the components of the electric system

20. The system of claim 15, wherein the coupling unit comprises a multiplexer circuit.
